(19) United States
(12) Patent Application Publication
(10) Pub. No.: US 2008/0265359 A1
(43) Pub. Date: Oct. 30, 2008

(54) SEMICONDUCTOR DIVICE

(76) Inventors: Masaaki Noda, Shiga (JP); Tomonari Oota, Toyama (JP)

Correspondence Address: MCDERMOTT WILL & EMERY LLP, 600 13TH STREET, NW, WASHINGTON, DC, 20005-3096, US

(21) Appl. No.: 12/104,048

(22) Filed: Apr. 16, 2008

(30) Foreign Application Priority Data
Apr. 25, 2007 (JP) 2007-116158

(51) Int. Cl. H01L 23/58

(52) U.S. Cl. 257/495; 257/E23.002

(57) ABSTRACT

A semiconductor device in the present invention is provided with a cathode layer of an N-type impurity region and an anode layer of a P-type impurity region formed on the cathode layer. A plurality of floating ring layers of the P-type impurity regions which is electrically floating is provided spaced apart from the anode layer on the main surface of the cathode layer. Then, well layers of the N-type impurity regions containing floating ring layers are provided. For example, each well layer can individually be provided to the floating ring layer. In this case, each floating ring layer may be spaced apart or overlapped one another. Accordingly, a semiconductor device serves to downsize a chip without changing a property of on-resistance or a breakdown voltage.

### CROSS-REFERENCE TO RELATED APPLICATION

The present application claims the benefit of patent application number 2007-116158, filed in Japan on Apr. 25, 2007, the subject matter of which is incorporated herein by reference.

### BACKGROUND OF THE INVENTION

1. Field of the Invention

The present invention relates to a semiconductor device, and more particularly to a semiconductor device having a floating ring.

2. Description of the Related Art

A vertical-type semiconductor device wherein the current flows between electrodes provided on both surfaces of a semiconductor substrate has been conventionally used as a power semiconductor device. As a semiconductor device of this type, diodes, MOS (Metal Oxide Semiconductor) transistors, IGBTs (Insulated Gate Bipolar Transistors), and thyristors are known (for example, see Japanese Laid-Open Patent Publication No. 8-167619).

FIG. 6 is a cross-sectional view showing a conventional vertical-type diode. FIG. 6 is a schematic view and the components are not shown in their actual scale ratios.

As shown in FIG. 6, in the conventional vertical-type diode, there is provided a cathode layer 103 consisting of a low concentration N-type impurity region and an anode layer 101 consisting of a P-type impurity region formed in the surface portion of the cathode layer 103. A contact layer 105 consisting of a high concentration P-type impurity region is formed in the surface portion of the anode layer 101, and an anode electrode 106 is formed on the upper side of the contact layer 105. Further, a cathode electrode 108 is formed on the underside of the cathode layer 103.

Further, when the vertical-type diode must have high breakdown voltage, a plurality of floating ring layers 102 (102a, 102b, 102c) each consisting of a high concentration P-type impurity region is provided around a PN junction comprised of the cathode layer 103 and the anode layer 101, being spaced apart from the anode layer 101. A channel stopper layer 107 consisting of an N-type impurity region is provided around the outermost floating ring layer 102c, being spaced apart therefrom. The floating ring layers 102 are electrically floating.

In the above-described conventional structure, when a reverse voltage is applied between the anode electrode 106 and the cathode electrode 108, a depletion layer extends through the cathode layer 103 from the PN junction comprised of the anode layer 101 and the cathode layer 103 as the reverse voltage is increased. When the reverse voltage is further increased, the depletion layer having extended through the cathode layer 103 further extends and reaches the innermost floating ring layer 102a. The floating ring layers 102 consisting of impurity regions have a surface impurity concentration of an exponent of 18 or higher so that the floating ring layers 102 have a nearly uniform potential. Then, the depletion layer reached the innermost floating ring layer 102a passes through the floating ring layer 102a and further extends through the cathode layer 103 between the floating ring layer 102a and the next floating ring layer 102b. When the difference in potential between the anode electrode 106 and the cathode electrode 108 reaches a rated voltage, the edge of the depletion layer reaches near the channel stopper layer 107.

FIG. 7 is a cross-sectional view schematically showing a potential distribution when a specific reverse voltage is applied between the anode electrode 106 and the cathode electrode 108. Equipotential lines are shown by broken lines in FIG. 7. As shown in FIG. 7, the floating ring layers 102 locate the edge of the main surface of the depletion layer extending along the contour of the anode layer 101 away from the anode layer 101 when a reverse voltage is applied between the anode and the cathode. The floating ring layers 102 serve to reduce the curvature of the equipotential lines so as to prevent the breakdown due to electric field concentration. In the structure shown in FIG. 7, the electric field is apt to concentrate around the bottom corner of the anode layer 101 (marked by an arrow A in FIG. 7) and the bottom corner of the innermost floating ring layer 102a on the anode layer 101 side (marked by an arrow B in FIG. 7). Therefore, the impurity concentration of the anode layer 101 and the cathode layer 103 is proposed under the condition that the breakdown does not occur around these positions when the rated voltage (reverse direction) is applied.

### SUMMARY OF THE INVENTION

In the conventional structure, the distance between the anode layer 101 and the channel stopper layer 107 (the total width of the cathode layer 103) is determined based on the extension of the depletion layer when the rated voltage is applied between the cathode and the anode. In other words, the total width of the cathode layer 103 is established so that the edge of the depletion layer reaches near the channel stopper layer 107 when the rated voltage is applied between the cathode and the anode.

When the PN junction is a one-sided abrupt junction (the N-type region is the one with a low concentration), the width W of the depletion layer is expressed by the equation 1 below in which Kₛ is the silicon relative dielectric constant, C_{B} is the N-type region impurity concentration, ∈₀ is the vacuum dielectric constant, q is the electron electric charge and V is the reverse potential:

W=(2Kₛ∈₀V/qC_{B})^{1/2} (1)

As shown in the equation 1, the width W of the depletion layer is inversely proportional to the square root of the N-type region impurity concentration C_{B}. Therefore, the width W of the depletion layer is decreased as the N-type region impurity concentration C_{B} is increased. In the above-described conventional structure, the regions between one floating ring layer and the next are the cathode layer 103 consisting of the N-type low concentration impurity layer. For example, when the diode has a reverse breakdown voltage of approximately 300V, the cathode layer 103 has an impurity concentration in the order of an exponent of 14.

In the conventional structure, since the cathode layer 103 has a low concentration, the extension of the depletion layer through the cathode layer 103 is large (see the equation 1). Therefore, the total width of the cathode layer 103 between the anode layer 101 and channel stopper layer 107 is increased. For example, when the diode has a cathode-anode breakdown voltage (BVCA) of approximately 300V, the total width of the cathode layer 103 from the edge of the anode layer 101 to the channel stopper layer 107 has to be approximately 200 μm. For that reason, the chip size is disadvantageously increased in the conventional structure.

The present invention is proposed in view of the above-described circumstances and the purpose of the present invention is to provide a semiconductor device that may reduce a chipsize without changing the property of the on-resistance and the breakdown voltage.

The present invention employs the following technical means in order to solve the above-described problems. The semiconductor device in accordance with the present invention is provided with a first semiconductor layer consisting of a first conductivity type impurity region. A second semiconductor layer consisting of a second conductivity type impurity region is provided on the first semiconductor layer. A plurality of floating ring layers consisting of the second conductivity type impurity regions (third semiconductor layers) which is electrically floating is provided spaced apart from the second semiconductor layer on the main surface of the first semiconductor layer. The semiconductor device of the present invention further provides a well layer consisting of the first conductivity type impurity region (a fourth semiconductor layer) containing the floating ring layer.

For example, the above-described well layer is individually formed to the each floating ring layer. In this case, each well layer may be formed spaced apart or overlapped one another. Further, in this case, it is preferable that a pair of the well layers on both sides of one floating ring layer is disposed in a state that a width of the well layer on the side away from the second semiconductor layer is larger than a width of the well layer on the side closer to the second semiconductor layer in plane view. Furthermore, it is preferable that a width of the well layer on either side of one floating ring layer is larger than a width of the well layer on either side of another floating ring layer closer to the second semiconductor layer in plane view.

It is noted that the second semiconductor layer and the floating ring layers may be formed in the same process of forming impurity regions at the same time.

According to the present invention, providing the well layer containing the floating ring layer allows a distance between the second semiconductor layer and a channel stopper layer formed outside of the floating ring layers to be decreased without changing on-resistance and a breakdown voltage, thereby a chip is downsized. Further, when a pair of the well layers on both sides of one floating ring layer is disposed in a state that the width of the well layer on the side away from the second semiconductor layer is larger than the width of the well layer on the side closer to the second semiconductor layer in plane view, the distance between the second semiconductor layer and the channel stopper layer can be decreased. Furthermore, the width of the well layer on either side of one floating ring layer is larger lager than the width of the well layer on either side of another floating ring layer closer to the second semiconductor layer in plane view, the distance between the second semiconductor layer and the channel stopper layer can further be decreased.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view showing a semiconductor device in accordance with First Embodiment of the present invention.

FIG. 2 is a cross-sectional view showing a semiconductor device in accordance with First Embodiment of the present invention.

FIG. 3 is a plan view showing a modification of a semiconductor device in accordance with First Embodiment of the present invention.

FIG. 4 is a cross-sectional view showing a semiconductor device in accordance with Second Embodiment of the present invention.

FIG. 5 is an enlarged plan view showing a semiconductor device in accordance with Second Embodiment of the present invention.

FIG. 6 is a cross sectional view showing a conventional semiconductor device.

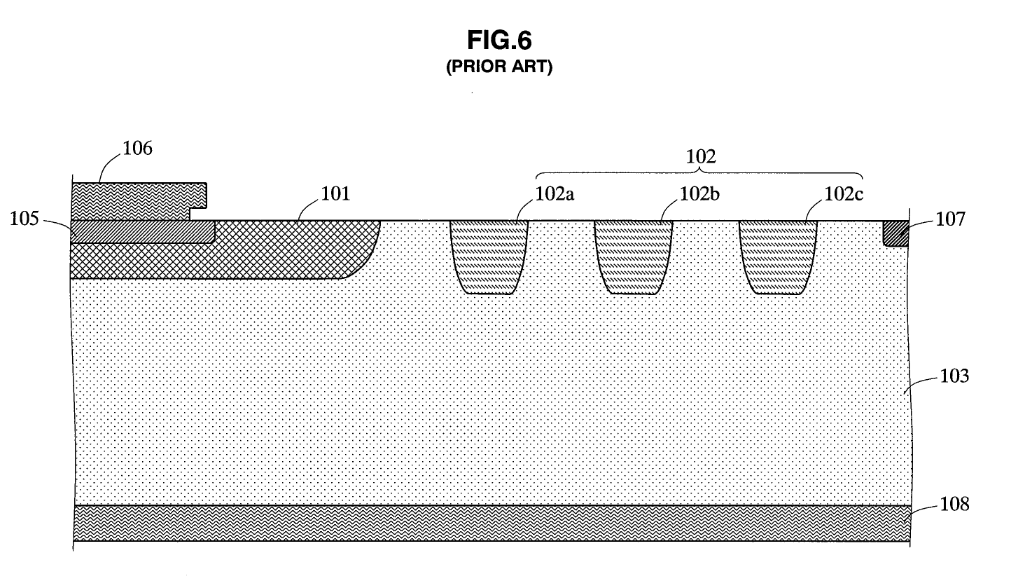

FIG. 7 is a cross-sectional view showing a potential distribution in a conventional semiconductor device.

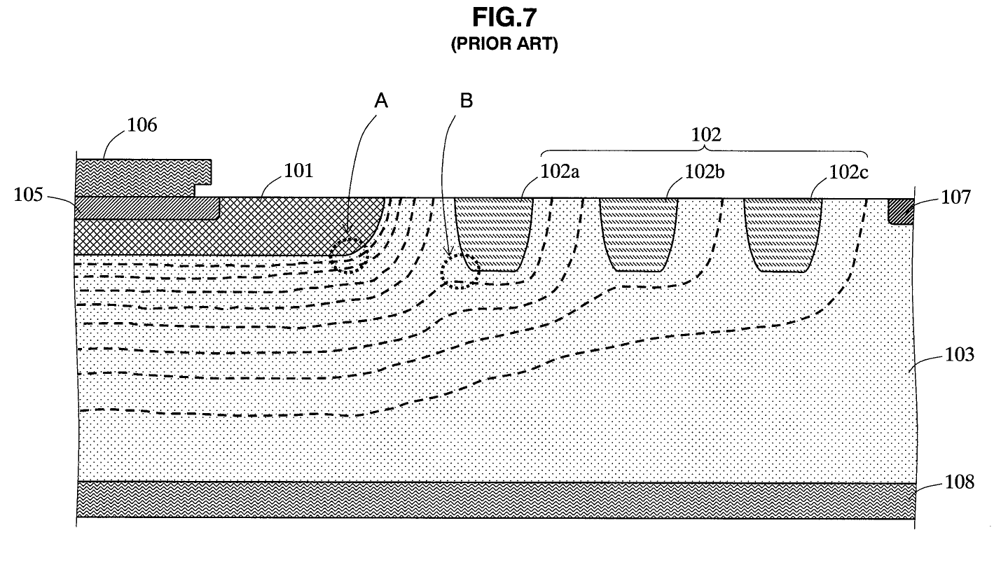

### DETAILED DESCRIPTION OF PREFERRED EMBODIMENTS

Embodiments of the present invention will be described in detail hereafter with reference to the drawings. In the following embodiments, the present invention is specified as a semiconductor device containing a vertical-type diode wherein a cathode electrode and an anode electrode are formed on different surfaces.

### First Embodiment

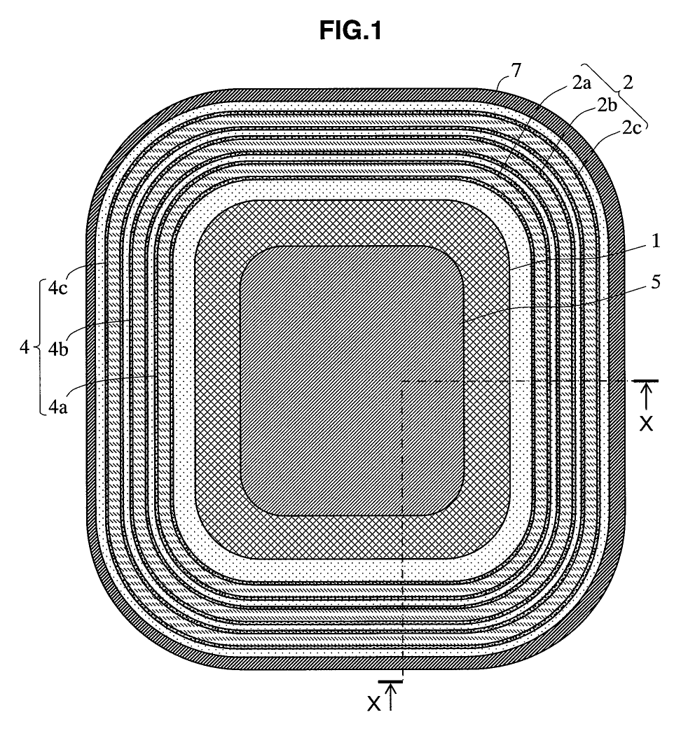

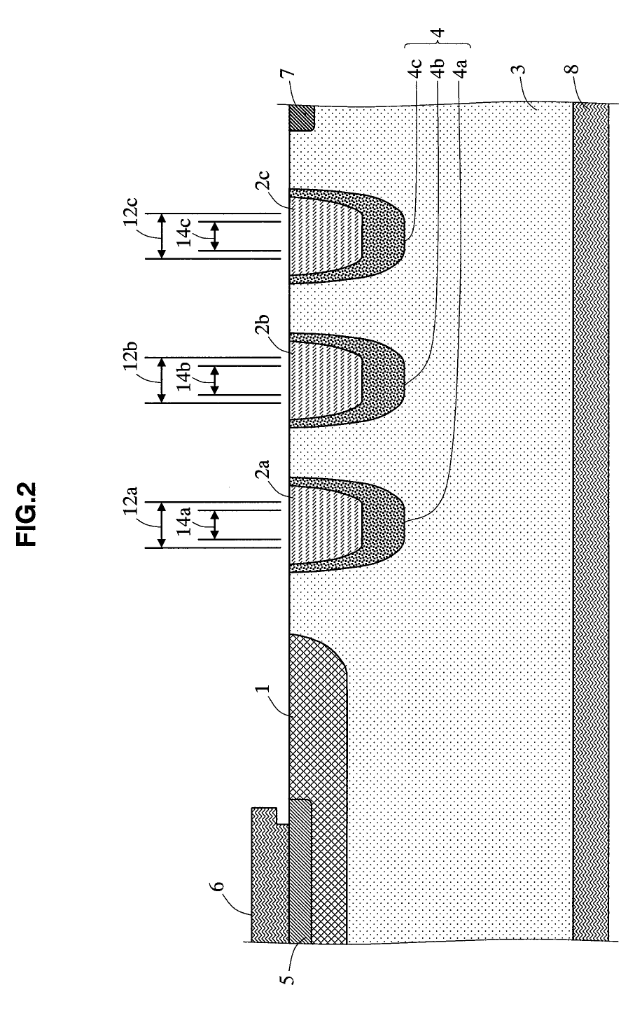

FIG. 1 is a plan view showing a structure of a semiconductor device in accordance with the first embodiment of the present invention. FIG. 2 is a cross-sectional view taken along a line X-X in FIG. 1. FIGS. 1 and 2 are schematic views and the components are not shown in their actual scale ratios.

As shown in FIG. 2, the semiconductor device in this embodiment is provided with a cathode layer 3 (a first semiconductor layer) consisting of a low concentration N-type impurity region. A cathode electrode 8 is formed on the underside of the cathode layer 3.

Further, an anode layer 1 (a second semiconductor layer) consisting of a P-type impurity region is provided in an upper part of the cathode layer 3. A contact layer 5 consisting of a high concentration P-type impurity region is formed on the main surface of the anode layer 1, and an anode electrode 6 is formed on the upper side of the contact layer 5. The anode electrode 6 is not shown in the plane view of FIG. 1.

On the other hand, as shown in FIGS. 1 and 2, a plurality of floating ring layers 2 (third semiconductor layers) each consisting of a high concentration P-type impurity region is provided around the anode layer 1, being spaced apart from the anode layer 1 and surrounding the anode layer 1. In this embodiment, three floating ring layers 2a, 2b and 2c having the same width are disposed at equal intervals in plane view. A channel stopper layer 7 consisting of a high concentration N-type impurity region is provided around the outermost of the floating ring layer 2c, being spaced apart from the floating ring layer 2c. The floating ring layers 2 locate an edge of a main surface of a depletion layer extending along the contour of the anode layer 1 away from the anode layer 1 when a reverse voltage is applied between the anode and the cathode. The floating ring layers 2 serve to reduce the curvature of the edge of the depletion layer so as to prevent breakdown due to electric field concentration. Each floating ring layer 2 is electrically floating. A given potential is applied to the channel stopper layer 7 to prevent the depletion layer from extending beyond the region of the diode element.

As shown in FIGS. 1 and 2, the semiconductor device of this embodiment has well layers 4 (fourth semiconductor layers) containing the floating ring layers 2 respectively. More specifically, the well layers 4 (4a, 4b, 4c) have bottoms positioned deeper than the floating ring layers 2 and respectively contain the floating ring layers 2 (2a, 2b, 2c) in plane view. The well layers 4 are N-type impurity regions, and have an impurity concentration lower than the floating ring layers 2 and higher than the cathode layer 3. For example, as shown in FIG. 2, the well layers 4 are formed by ion-implantation of N-type impurities in portions 14 (14a, 14b, 14c) contained in ion-implanted portions 12 (12a, 12b, 12c) for forming each floating ring layer 2a, 2b, 2c. Then, the N-type impurities ion-implanted for forming the well layers 4 diffuse horizontally and consequently form the well layers 4 respectively containing the floating ring layers 2, respectively.

In the structure of this embodiment, the N-type well layers 4 having a higher impurity concentration than the cathode layer 3 are disposed in surface portions between the anode layer 1 and the channel stopper layer 7. In this structure, when a reverse voltage is applied between the anode and the cathode, the depletion layer extends in the anode layer 1 and the cathode layer 3 from a PN junction comprised of the anode layer 1 and the cathode layer 3 as a difference in potential is increased. Then, when the reverse voltage is further increased, the depletion layer having extended through the cathode layer 3 reaches the well layer 4a containing the floating ring layer 2a before it reaches the innermost floating ring layer 2a. As described above, the well layer 4a has a higher impurity concentration than the cathode layer 3. Therefore, the depletion layer extends at a lower rate in the well layer 4a than in the cathode layer 3 (see the equation 1). Then, the edge of the depletion layer reaches the floating ring layer 2a when a higher reverse voltage is applied as compared to the conventional structure. Having reached the floating ring layer 2a, the depletion layer passes through the floating ring layer 2a and again extends through the well layer 4a and then the cathode layer 3 between the floating ring layer 2a and the next floating ring layer 2b. When the edge of the depletion layer reaches the floating ring layers 2b and 2c, the depletion layer extends at a lower rate because of the well layers 4b and 4c as compared to the conventional structure.

Therefore, when a specific reverse voltage is applied between the cathode and the anode, the edge of the depletion layer locates closer to the anode layer 1 as compared to the conventional structure. Therefore, in this structure, the distance between the anode layer 1 and the channel stopper layer 7 can be reduced as compared to the conventional structure. Further, the well layers 4 are formed only around the floating ring layers 2, thereby that does not affect the structure the anode layer 1 and their immediate surrounding. As a result, according to this structure, a chip can be downsized without changing the on-resistance and the cathode-anode breakdown voltage.

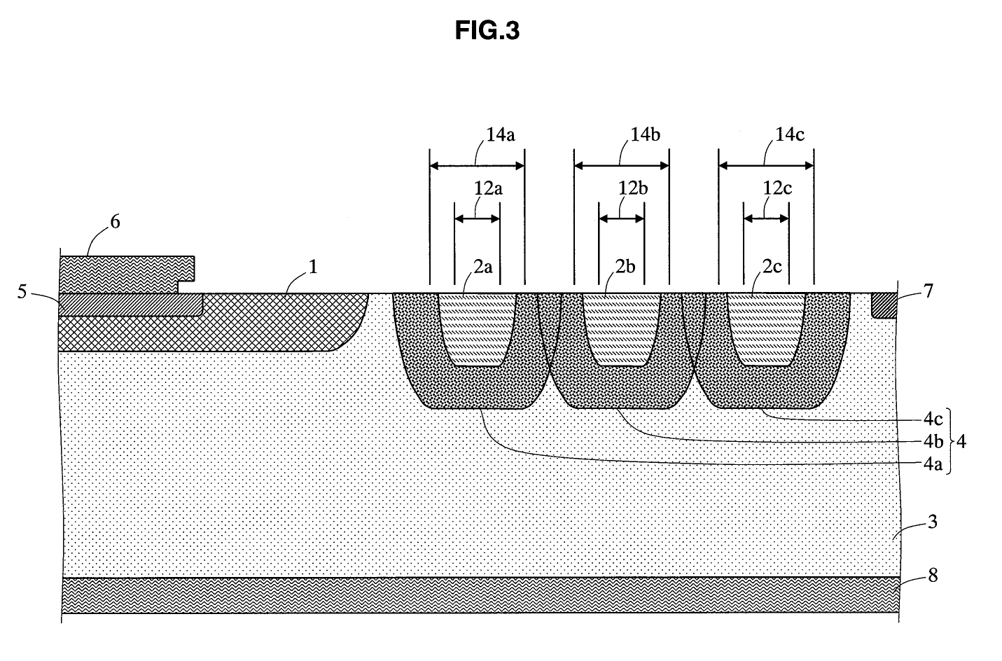

Incidentally, in this embodiment shown in FIGS. 1 and 2, the well layers 4 are respectively formed around the floating ring layers 2a to 2c spaced apart one another. However, it is not essential to dispose each well layer 4a, 4b, 4c spaced apart. FIG. 3 is a cross-sectional view showing a modification of a semiconductor device of the present embodiment. As in FIG. 2, FIG. 3 is a cross-sectional view taken along the line X-X in FIG. 1. FIG. 3 is a schematic view and the components are not shown in their actual scale ratios. In FIG. 3, the same components as those of the semiconductor device in FIG. 2 are referred to by the same reference numbers.

As shown in FIG. 3, in this modification, the well layers 4 (4a to 4c) respectively contain floating ring layers 2 (2a to 2c) and have the bottoms deeper than the bottoms of the floating ring layers 2. The well layers 4 are N-type impurity regions. The well layers 4 have an impurity concentration lower than the floating ring layers 2 and higher than the cathode layer 3. In the structure shown in FIG. 3, the well layers 4 can be formed for example by ion-implantation of N-type impurities in portions 14 (14a, 14b, 14c) containing ion-implanting portions 12 (12a, 12b, 12c) for forming the floating ring layers 2.

In this structure, the N-type well layers 4 having a higher concentration than the cathode layer 3 are provided in surface portions between the anode layer 1 and the channel stopper layer 7 more extensively than the structure shown in FIG. 2. Thus, the impurity concentration of the N-type region from the anode layer 1 to the channel stopper layer 7 is higher than in the structure shown in FIG. 2, thereby the depletion layer extends at a lower rate. In this structure, the distance between the anode layer 1 and the channel stopper layer 7 can further be reduced as compared to the structure shown in FIG. 2.

In the above modification, each well layer 4 is formed as an individual impurity region. However, it is not essential to form each of the well layers as an individual impurity region. The well layers 4 can be formed as a single impurity region containing multiple floating ring layers.

### Second Embodiment

In the first embodiment, the structure to reduce the extension of the depletion layer equally in each of the floating ring layers is described. However, in view of reducing the curvature of the contour of the depletion layer edge, it is preferable that the depletion layer extends less as it is away from the anode layer. Then, preferable positioning of the well layers is descried in the second embodiment of the present invention.

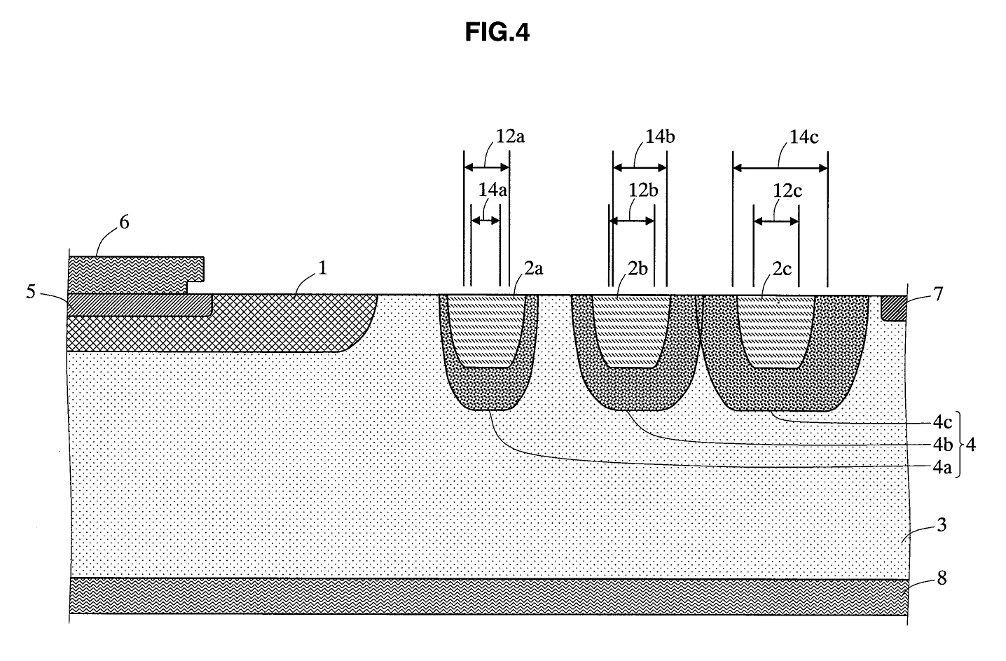

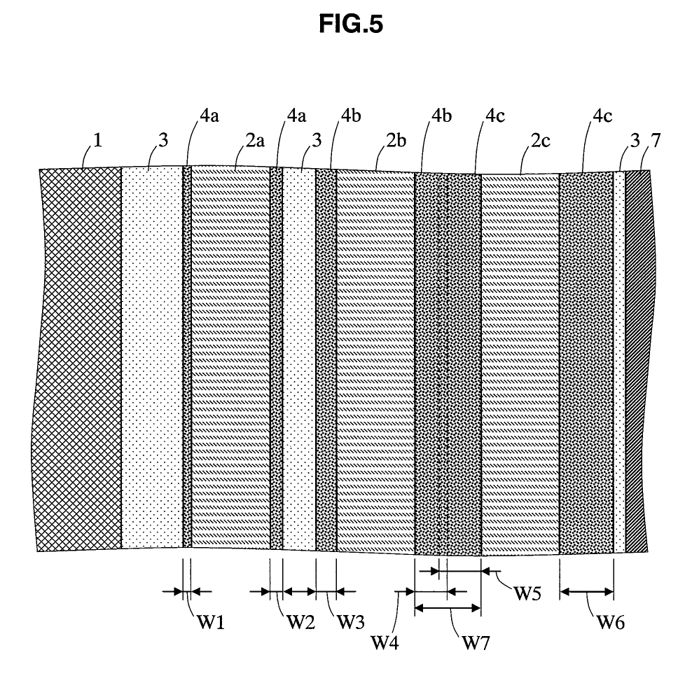

FIG. 4 is a cross-sectional view showing a structure of a semiconductor device in this embodiment. The semiconductor device of this embodiment has the same planar structure as that in the plan view of FIG. 1 except for the structure around each floating ring layer. FIG. 4 corresponds to the cross-sectional structure at the line X-X in FIG. 1. FIG. 4 is a schematic view and the components are not shown in their actual scale ratios. FIG. 5 is a plan view showing the region shown in FIG. 4. In FIGS. 4 and 5, the same components as those in the first embodiment are referred to by the same reference numbers.

As in the semiconductor device of the first embodiment, the semiconductor device of this embodiment comprises the well layers 4 (4a to 4c) containing each floating ring layer 2 (2a to 2c). The well layers 4 are N-type impurity regions, and have an impurity concentration lower than the floating ring layers 2 and higher than the cathode layer 3. In this embodiment, each well layer 4a to 4c is unsymmetrically formed with respect to each floating ring layer 2a to 2c. In other words, the well layers 4 are present on the sides of the floating ring layers 2, having a width larger on the side away from the anode layer 1 than on the side closer to the anode layer 1 in plane view. As shown in FIG. 5, a width W2 of the well layer 4a on the side of the floating ring layer 2a which is away from the anode layer 1 is larger than a width W1 of another well layer 4a which is closer to the anode layer 1. A width W4 of the well layer 4b on the side of the floating ring layer 2b which is away from the anode layer 1 is larger than a width W3 of another well layer 4b which is closer to the anode layer 1. A width W6 of the well layer 4c on the side of the floating ring layer 2c which is away from the anode layer 1 is larger than a width W5 of another well layer 4c which is closer to the anode layer 1.

Additionally, in this embodiment, at least one of the widths (W1, W2, W3, W7 and W6 from the anode layer 1 side) of the well layers 4 present on the sides of each floating ring layer 2a, 2b, 2c is larger than the width of other inner well layers 4 in plane view. Here, particularly, the well layers 4 are formed in the manner that each width of the well layers 4 present on the sides of each floating ring layer 2a, 2b,2c is increased from the anode layer 1 side (W1<W2<W3<W7).

The well layers 4 as described above can be formed, for example, by ion-implantation of N-type impurities in a portion 14a contained in an ion-implanting portion 12a for forming the floating ring layer 2a, a portion 14b partly containing an ion-implanting portion 12b for forming the floating ring layer 2b, and a portion 14c containing an ion-implanting portion 12c for forming the floating ring layer 2c. The center lines of the portions 14a, 14b and 14c are shifted toward the channel stopper layer 7 from the center lines of the portions 12a, 12b and 12c, respectively.

In the structure of this embodiment, the N-type well layers 4 having a higher impurity concentration than the cathode layer 3 are disposed in surface portions between the anode layer 1 and the channel stopper layer 7. Then, the width of each well layer 4 present on the sides of each floating ring layer 2a, 2b, 2c is increased in order from the anode layer 1 side (W1<W2<W3<W7).

When a reverse voltage is applied between the cathode and the anode, the electric field strength in a PN junction comprised of the floating ring layer 2 and the well layer 4 is higher in a PN junction closer to the anode layer 1 than in a PN junction away from the anode layer 1. For example, the electric field strength in the PN junction comprised of the floating ring layer 2a and the well layer 4a is higher than the electric field strength in the PN junction comprised of the floating ring layer 2b and the well layer 4b.

When a pair of the well layers 4 on both sides of respective floating ring layers 2 is disposed in a state that the well layer width on the side away from the anode layer 1 is larger than the well layer width on the side closer to the anode layer 1 in plane view, the N-type impurity concentration on the side closer to the anode layer 1 is lower than the N-type impurity concentration on the side away from the anode layer 1. Namely, the N-type impurity concentration can be lowered on the side where electric field strength is higher. Further, when the well layers 4 are disposed in a state that the well layer width on either side of one floating ring layer 2 closer to the anode layer 1 is smaller than the well layer width on either side of another floating ring layer 2 away from the anode layer 1 in plane view, the N-type impurity concentration can be lowered in the region where the electric field strength is higher.

Therefore, disposing the well layers 4 as described above serves to effectively ease the electric field strength in the PN junctions of the floating ring layers 2 with higher electric field strength closer to the anode layer 1. As a result, the cathode-anode breakdown voltage (reverse breakdown voltage) can be improved. Namely, the distance between the anode layer 1 and the channel stopper layer 7 can be reduced for the same cathode-anode breakdown voltage, thereby downsizing the chip.

In this embodiment, two structures are simultaneously used. Namely, one is that the each well layer has the smaller width on the anode layer side than the other side in respective floating ring layers, in plane view, and the other is that the well layer closer to the anode layer has a smaller width than the well layer away from the anode layer in other different floating ring layers. However, it is not necessarily essential to combine those two structures. Only one structure can be used. Even when only one of these structures is used, the cathode-anode breakdown voltage can be improved and the chip can be downsized as compared to the first embodiment. In addition, it is described in the above as a particularly preferred embodiment that the width of the well layer is increased in order from the anode layer 1 side. However, at least one of the widths of the well layers on the sides of the floating ring layers 2 may be larger than the widths of other well layers closer to the anode layer 1 in plane view.

Furthermore, in this embodiment, all floating ring layers are provided with the well layers, however, not all floating ring layers may be provided with the well layers.

As described above, according to the present invention, the semiconductor device provided with a PN junction comprised by the first semiconductor layer and the second semiconductor layer of a reverse conductivity type provided on the first semiconductor layer leads to downsizing of the chip without changing the property of the on-resistance and the breakdown voltage.

The above embodiments are described by way of example and do not restrict the present invention. Various modifications and applications are available without departing from the technical idea of the present invention. For example, the anode layer and the floating ring layers can be formed in the same process of forming impurity regions at the same time in the above embodiments. In such a case, a number of masks used for manufacturing a semiconductor device and a number of manufacturing process steps of a semiconductor device can be reduced, thereby production costs are decreased. Further, although the present invention is described for a semiconductor device containing a vertical-type diode, the present invention is also applicable for a semiconductor device containing a vertical-type MOS transistor, a vertical-type IGBT and a vertical-type thyristor. Furthermore, the present invention is applicable for a lateral-type semiconductor device wherein current flows between electrodes provided on the same substrate such as a lateral-type diode, a lateral-type MOS transistor, a lateral-type IGBT and a lateral-type thyristor. In other words, the present application is applicable for any semiconductor devices having a floating ring layer.

The present invention can downsize a chip while maintaining on-resistance and the breakdown voltage and is useful as a semiconductor device.

What is claimed is:

1. A semiconductor device comprising:
a first semiconductor layer of a first conductivity type impurity region;
a second semiconductor layer of a second conductivity type impurity region formed on the first semiconductor layer;
a plurality of third semiconductor layers of the second conductivity type impurity regions which is formed spaced apart from the second semiconductor layer on the main surface of the first semiconductor layer and is electrically floating; and
a fourth semiconductor layer of the first conductivity type impurity region containing the third semiconductor layer.

2. A semiconductor device according to claim 1, wherein the fourth semiconductor layer is individually formed to the each third semiconductor layer.

3. A semiconductor device according to claim 2, wherein
in plane view, a pair of the fourth semiconductor layers on both sides of the third semiconductor layer is disposed in a state that a width of the fourth semiconductor layer on the side away from the second semiconductor layer is larger than a width of the fourth semiconductor layer on the side closer to the second semiconductor layer.

4. A semiconductor device according to claim 2, wherein
in plane view, a width of the fourth semiconductor layer on either side of one of the third semiconductor layers is larger than a width of fourth semiconductor layer on either side of another third semiconductor layer closer to the second semiconductor layer.

5. A semiconductor device according to claim 3, wherein
in plane view, a width of the fourth semiconductor layer on either side of one of the third semiconductor layers is larger than a width of fourth semiconductor layer on either side of another third semiconductor layer closer to the second semiconductor layer.

6. A semiconductor device according to claim 1, wherein the second semiconductor layer and the third semiconductor layers are formed in the same process of forming impurity regions at the same time.

7. A semiconductor device according to claim 2, wherein the second semiconductor layer and the third semiconductor layers are formed in the same process of forming impurity regions at the same time.

8. A semiconductor device according to claim 3, wherein the second semiconductor layer and the third semiconductor layers are formed in the same process of forming impurity regions at the same time.

9. A semiconductor device according to claim 4, wherein the second semiconductor layer and the third semiconductor layers are formed in the same process of forming impurity regions at the same time.

10. A semiconductor device according to claim 5, wherein the second semiconductor layer and the third semiconductor layers are formed in the same process of forming impurity regions at the same time.
